(19) United States
(12) Patent Application Publication
(10) Pub. No.: US 2023/0343588 A1
(43) Pub. Date: Oct. 26, 2023

(54) SEMICONDUCTOR STRUCTURE AND METHOD OF FABRICATING THE SAME

(71) Applicant: GlobalWafers Co., Ltd., Hsinchu (TW)

(72) Inventors: Po Jung Lin, Hsinchu (TW); Jia-Zhe Liu, Hsinchu (TW)

(73) Assignee: GlobalWafers Co., Ltd., Hsinchu (TW)

(21) Appl. No.: 18/297,657

(22) Filed: Apr. 10, 2023

(30) Foreign Application Priority Data
Apr. 22, 2022 (TW) 111115529

(51) Int. Cl. H01L 21/02

(52) U.S. Cl. CPC H01L 21/02458; H01L 21/02378; H01L 21/0254

(57) ABSTRACT

A semiconductor structure includes a silicon carbide (SiC) substrate, a nucleation layer and a gallium nitride (GaN) layer. The silicon carbide layer has a first thickness T1. The nucleation layer is located on the silicon carbide layer and has a second thickness T2. The nucleation layer is made of AlGaN (AlGaN), and the second thickness T2 fulfills a thickness range of T1*0.002% to T1*0.006%. The gallium nitride layer is located on the nucleation layer and is separated from the silicon carbide substrate.

### CROSS REFERENCE TO RELATED APPLICATION

This application claims the priority benefit of Taiwan application serial no. 111115529, filed on Apr. 22, 2022. The entirety of the above-mentioned patent application is hereby incorporated by reference herein and made a part of this specification.

### BACKGROUND

### Technical Field

The present disclosure related to a semiconductor structure, in particular, relates to a semiconductor structure and a method of fabricating the same.

### Description of Related Art

To grow a gallium nitride (GaN) epitaxial layer on a silicon carbide (SiC) substrate, it is usually necessary to form an aluminum nitride as a buffer layer or a wetting layer in between the silicon carbide substrate and the gallium nitride epitaxial layer to facilitate the growth of gallium nitride. For example, if gallium nitride is directly grown on the silicon carbide substrate, it will lead to three-dimensional (3D) growth of the gallium nitride, making the surface of the gallium nitride rough, and subsequent epitaxial growth cannot be performed. Therefore, the general method of forming the gallium nitride epitaxial layer requires the use of aluminum nitride. However, aluminum nitride has a high resistance value, and usually needs to be grown at high temperature, and its bow is not easily controlled. In view of the above, how to control the formation of the gallium nitride epitaxial layer so that the semiconductor structure has good geometric quality is an urgent problem that needs to be solved.

### SUMMARY

The present disclosure provides a semiconductor structure, which forms a gallium nitride layer on a nucleation layer made of aluminum gallium nitride (AlGaN), so that the semiconductor structure has good geometrical quality.

The semiconductor structure of the present disclosure includes a silicon carbide substrate, a nucleation layer and a gallium nitride layer. The silicon carbide substrate has a first thickness T1. The nucleation layer is located on the silicon carbide substrate and has a second thickness T2. The nucleation layer is composed of AlGaN, and the second thickness T2 is in a thickness range of T1*0.002% to T1*0.006%. The gallium nitride layer is located on the nucleation layer and spaced apart from the silicon carbide substrate.

In one embodiment of the present disclosure, the second thickness T2 is in a thickness range of T1*0.002% to T1*0.007%.

In one embodiment of the present disclosure, the second thickness T2 is in a thickness range of T1*0.003% to T1*0.005%.

In one embodiment of the present disclosure, the AlGaN is represented by the following formula (1):

$${\text{Al}}_{\text{x}} \text{Ga} \left({}_{\text{100\%-x}}\right) \text{Nformula} \qquad \text{(1)}$$

wherein in formula (1), an aluminum content X is in a range of 20% to 60%.

In one embodiment of the present disclosure, the silicon carbide substrate is a 4-inch silicon carbide wafer substrate.

In one embodiment of the present disclosure, the AlGaN is represented by the following formula (1):

$${\text{Al}}_{\text{x}} \text{Ga} \left({}_{\text{100\%-x}}\right) \text{Nformula} \qquad \text{(1)}$$

wherein in formula (1), an aluminum content X is in a range of 30% to 50%.

In one embodiment of the present disclosure, the silicon carbide substrate is a 6-inch silicon carbide wafer substrate.

In one embodiment of the present disclosure, the semiconductor structure has a bow in a range of -25 µm to +25 µm.

In one embodiment of the present disclosure, the semiconductor structure has a bow in a range of -5 µm to +5 µm.

In one embodiment of the present disclosure, the gallium nitride layer has a third thickness T3, and the third thickness T3 is in a thickness range of T1*0.02% to T1*1%.

In one embodiment of the present disclosure, the gallium nitride layer has the third thickness T3, and the third thickness T3 is in a thickness range of T1*0.04% to T1*0.5%.

In one embodiment of the present disclosure, the gallium nitride layer has the third thickness T3, and the third thickness T3 is in a thickness range of T1*0.1% to T1*0.3%.

In one embodiment of the present disclosure, the first thickness T1 is 500 µm.

In one embodiment of the present disclosure, the second thickness T2 is 20 nm.

In one embodiment of the present disclosure, the nucleation layer includes an AlGaN layer, the AlGaN layer includes a first side and a second side opposite to the first side, the first side is in contact with the silicon carbide substrate, and the second side is in contact with the gallium nitride layer, and an aluminum content in the AlGaN layer decreases from the first side to the second side.

In one embodiment of the present disclosure, the aluminum content in the AlGaN layer decreases in a linear manner.

In one embodiment of the present disclosure, the aluminum content in the AlGaN layer decreases in a non-linear manner.

The present disclosure further provides a method of fabricating a semiconductor structure. The method includes the following steps. A regression plot diagram of a ratio of an aluminum content in AlGaN versus a bow of a semiconductor structure is provided. An ideal bow of the semiconductor structure to be formed is set, and an ideal aluminum content is calculated according to the regression plot diagram. A silicon carbide substrate is provided. A nucleation layer composed of AlGaN is formed on the silicon carbide substrate according to the ideal aluminum content. A gallium nitride layer is formed on the nucleation layer.

In one embodiment of the present disclosure, the ideal bow is set in a range of -25 µm to +25 µm.

In one embodiment of the present disclosure, when the semiconductor structure is a semiconductor structure used in high-power devices or radio frequency devices, the ideal aluminum content is in a range of 50% to 60%.

In one embodiment of the present disclosure, when the semiconductor structure is a semiconductor structure used in optical devices, the ideal aluminum content is in a range of 20% to 50%.

Based on the above, in the semiconductor structure according to the embodiments of the present disclosure, by controlling a thickness of the nucleation layer composed of AlGaN and controlling an aluminum content in AlGaN, the formed AlGaN layer can be continuously grown in 2D form, and can be used in subsequent steps to form an epitaxial layer of gallium nitride with lower stress. Accordingly, the formed semiconductor structure has good geometric quality, and the bow can be controlled within an appropriate range.

### BRIEF DESCRIPTION OF THE DRAWINGS

FIG. 1 is a flowchart of a method of fabricating a semiconductor structure in accordance with an embodiment of the present disclosure.

FIG. 2A to FIG. 2B are regression plot diagrams of a ratio of an aluminum content in AlGaN versus a bow of a semiconductor structure.

FIG. 3A to FIGS. 3D are schematic cross-sectional views of a method of fabricating a semiconductor structure in accordance with an embodiment of the present disclosure.

### DESCRIPTION OF THE EMBODIMENTS

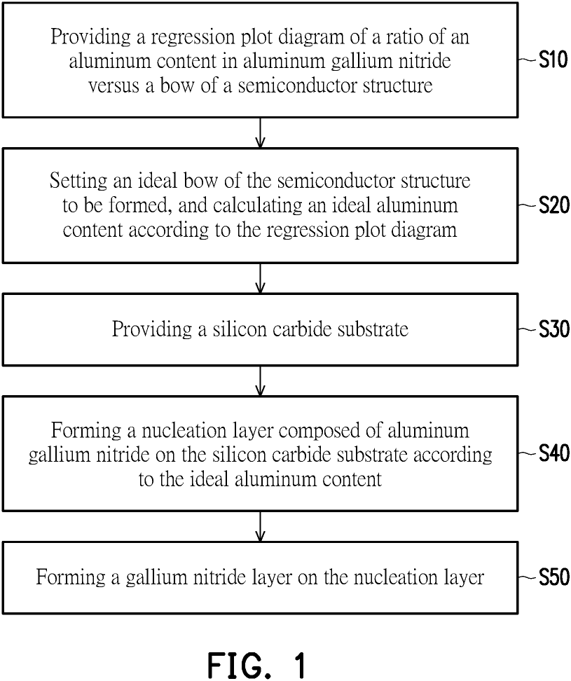

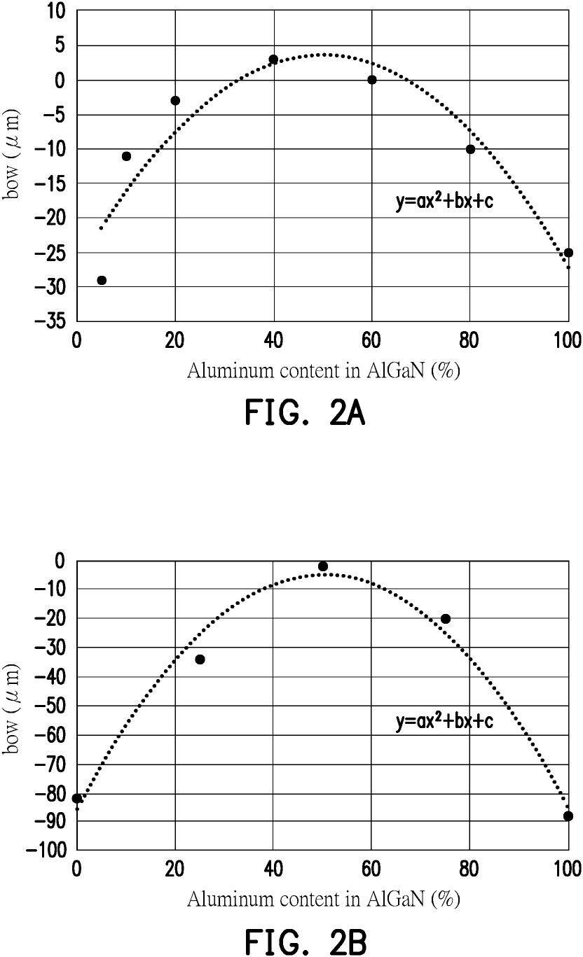

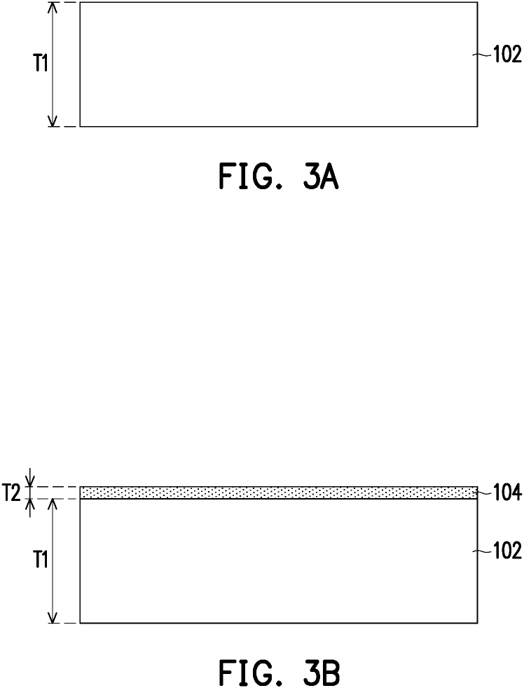

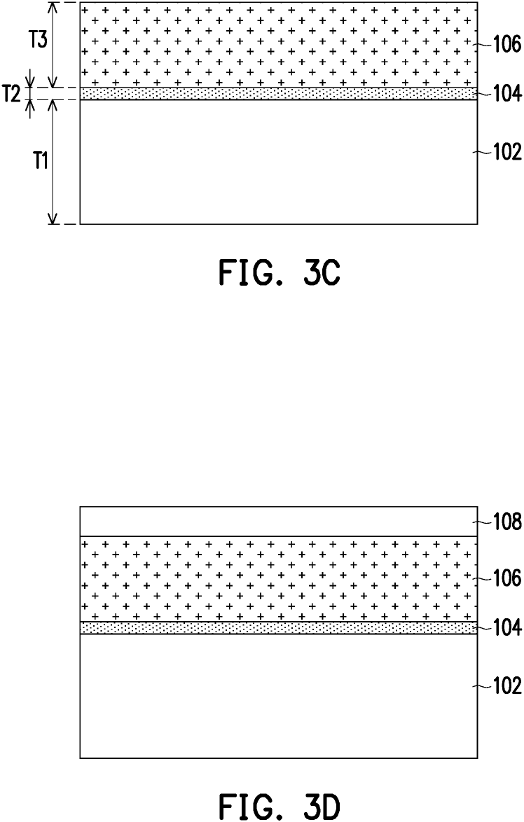

FIG. 1 is a flowchart of a method of fabricating a semiconductor structure in accordance with an embodiment of the present disclosure. The specific steps of the method of fabricating a semiconductor structure in accordance with an embodiment of the present disclosure will be described below with reference to FIG. 1 along with the regression plot diagrams shown in FIG. 2A to FIG. 2B and the schematic cross-sectional views shown in FIG. 3A to FIG. 3D.

Referring to step S10 of FIG. 1A, in some embodiments, a regression plot diagram of an aluminum content ratio in AlGaN (AlGaN) versus a bow of a semiconductor structure is provided. For example, AlGaN layers with different aluminum contents are formed on a silicon carbide wafer substrate, and the effect of the aluminum content ratio on the warpage of the semiconductor structure is confirmed. As shown in the experimental results presented in Table 1 and Table 2, AlGaN layers with different aluminum contents are formed on a 4-inch silicon carbide wafer substrate or a 6-inch silicon carbide wafer substrate, and a bow of the formed semiconductor structure is confirmed.

TABLE 1

silicon carbide wafer substrate (4-inch)

| Aluminum content of AlGaN (%) | Bow (µm) |
|---|---|
| 5 | -29 |
| 10 | -11 |
| 20 | -3 |
| 40 | 3 |
| 60 | 0 |
| 80 | -10 |
| 100 | -25 |

TABLE 2

silicon carbide wafer substrate (6-inch)

| Aluminum content of AlGaN (%) | Bow (µm) |
|---|---|
| 1 | -81 |
| 25 | -34 |
| 50 | -2 |
| 75 | -20 |
| 100 | -88 |

In some embodiments of the present disclosure, based on the experimental results shown in Table 1 and Table 2, the relationship between the aluminum content and the bow is calculated through a quadratic function (such as formula: y=ax²+bx+c) to obtain the regression plot diagram shown in FIG. 2A and FIG. 2B. As shown in FIG. 2A, it is a regression plot diagram corresponding to the formation of AlGaN on a 4-inch silicon carbide wafer substrate. In addition, as shown in FIG. 2B, it is a regression plot diagram corresponding to the formation of AlGaN on a 6-inch silicon carbide wafer substrate.

Subsequently, referring to step S20 of FIG. 1A, in some embodiments, an ideal bow of a semiconductor structure to be formed is set, and the corresponding ideal aluminum content is calculated according to the regression plot diagram. In some embodiments, the ideal bow is set in the range of -25 µm to +25 µm. In some preferred embodiments, the ideal bow is set within a range of -5 µm to +5 µm. Referring to FIG. 2A, if AlGaN is formed on a 4-inch silicon carbide wafer substrate, and when the ideal bow is set in the range of -5 µm to +5 µm, it can be known from the regression plot diagram in FIG. 2A that the ideal aluminum content for AlGaN is in the range of 20% to 60%. Referring to FIG. 2B, if AlGaN is formed on a 6-inch silicon carbide wafer substrate, and when the ideal bow is set in the range of -25 µm to +25 µm, it can be known from the regression plot diagram in FIG. 2B that the ideal aluminum content of AlGaN is in the range of 30% to 75%, and preferably in the range of 30% to 50%.

Taking a step further, if the semiconductor structure is used for high-power devices or radio frequency devices, the aluminum content can be increased to achieve a higher resistance value. Therefore, the ideal aluminum content can be estimated to be within the range of 50% to 60% from the regression plot diagram. In addition, if the semiconductor structure is used for optical devices, the aluminum content can be reduced to achieve a lower resistance value. Therefore, the ideal aluminum content can be estimated to be in the range of 20% to 50% from the regression plot diagram. Specifically, if AlGaN is formed on a 4-inch silicon carbide wafer substrate and used for semiconductor structures of high-power devices or radio-frequency devices, and when the ideal bow is set in the range of -5 µm to +5 µm, it can be seen from the regression plot diagram in FIG. 2A that the ideal aluminum content of AlGaN can be 50% to 60%. If the semiconductor structure is a semiconductor structure used for optical devices, the aluminum content can be reduced to achieve a lower resistance value. Therefore, the ideal aluminum content can be estimated to be in the range of 20% to 50% from the regression plot diagram. If AlGaN is formed on a 6-inch silicon carbide wafer substrate and used for semiconductor structures of high-power devices or radio-frequency devices, and when the ideal bow is set in the range of -25 µm to +25 µm, it can be seen from the regression plot diagram in FIG. 2B that the ideal aluminum content of AlGaN can be 50% to 75%. If the semiconductor structure is a semiconductor structure used for optical devices, the aluminum content can be reduced to achieve a lower resistance value. Therefore, the ideal aluminum content can be estimated to be in the range of 30% to 50% from the regression plot diagram. Accordingly, when the content of aluminum in AlGaN is controlled within the above range, the formed semiconductor structure can have good geometry and ideal bow. On the other hand, if the aluminum content in AlGaN exceeds the above-mentioned ranges, then the bow is too high, and a gallium nitride layer with good epitaxial quality cannot be obtained subsequently.

Next, referring to step S30 of FIG. 1A and FIG. 3A, in some embodiments, a silicon carbide substrate 102 is provided. The silicon carbide substrate 102 is a 4-inch silicon carbide wafer substrate or a 6-inch silicon carbide wafer substrate. In addition, the silicon carbide substrate 102 has a first thickness T1.

Subsequently, referring to step S40 of FIG. 1A and FIG. 3B, a nucleation layer 104 composed of AlGaN is formed on the silicon carbide substrate 102 based on the above ideal aluminum content. For example, if the silicon carbide substrate 102 is a 4-inch silicon carbide wafer substrate, the ideal aluminum content is in the range of 20% to 60%. In addition, if the silicon carbide substrate 102 is a 6-inch silicon carbide wafer substrate, the ideal aluminum content is in the range of 30% to 50%. In addition, according to whether the formed semiconductor structure is a high-power device, a radio frequency device or an optical device, the ideal aluminum content can be further adjusted to be more than 50% to achieve a higher resistance value, or adjusted to be less than 50% to achieve a lower resistance value.

For example, in the embodiment of the present disclosure, the AlGaN is represented by the following formula (1):

$${\text{Al}}_{\text{x}} \text{Ga} \left({}_{\text{100\%-x}}\right) \text{N} \qquad \text{formula (1)}$$

wherein in formula (1), when the silicon carbide substrate 102 is a 4-inch silicon carbide wafer substrate, the aluminum content X is in a range of 20% to 60%, and when the silicon carbide substrate 102 is a 6-inch silicon carbide wafer substrate, the aluminum content X is in a range of 30% to 50%.

In the embodiment of the present disclosure, an epitaxial process of the nucleation layer 104 is performed based on a concentration with the above ideal aluminum content. In some embodiments, the formed nucleation layer 104 includes an AlGaN layer. For example, the AlGaN layer includes a first side and a second side opposite to the first side, wherein the first side is in contact with the silicon carbide substrate 102, and the second side is in contact with the subsequently formed gallium nitride layer. According to the epitaxial method, the aluminum content in the AlGaN layer of the nucleation layer 104 can gradually decrease from the first side to the second side. For example, the first side of the AlGaN layer may have a higher aluminum concentration and the second side may have a lower aluminum concentration, but the overall aluminum content in the AlGaN layer (nucleation layer 104) is still within the range of the ideal aluminum content mentioned above.

In some embodiments, if the aluminum content in the AlGaN layer of the nucleation layer 104 decreases from the first side to the second side, the aluminum content in the AlGaN layer decreases in a linear manner. For example, based on the distance from the first side to the second side in the AlGaN layer, the aluminum content in the AlGaN layer can be proportionally decreased in a way that the aluminum content decreases by 1% for every 1 nm distance away from the first side. In another embodiment, if the aluminum content in the AlGaN layer of the nucleation layer 104 decreases from the first side to the second side, the aluminum content in the AlGaN layer can also decrease in a non-linear manner. For example, the non-linear decrease in aluminum content may include a stepwise decrease or a non-proportional decrease.

In some embodiments, the nucleation layer 104 is formed by metal-organic chemical vapor deposition (MOCVD). In addition, the nucleation layer 104 composed of AlGaN has a second thickness T2. In some embodiments, the second thickness T2 is a thickness within a range of T1*0.001% to T1*0.01%. In some preferred embodiments, the second thickness T2 is a thickness within the range of T1*0.002% to T1*0.007%. In some most preferred embodiments, the second thickness T2 is a thickness in the range of T1*0.003% to T1*0.005%. If the second thickness T2 and the first thickness T1 fulfill the above-mentioned proportional relationship, it can be further ensured that the formed semiconductor structure has a good geometry and an ideal bow.

In some embodiments, the second thickness T2 is, for example, a thickness in a range of 1 nm to 100 nm. In some specific embodiments, the second thickness T2 is, for example, a thickness in a range of 1 nm to 40 nm. In some preferred embodiments, the second thickness T2 is, for example, a thickness in a range of 15 nm to 25 nm. If the second thickness T2 is controlled within the above range, the formed AlGaN layer can be continuously grown in 2D form, and the formation of a gallium nitride epitaxial layer with lower stress in subsequent steps can be ensured.

Next, referring to step S50 of FIG. 1A and FIG. 3C, a gallium nitride layer 106 is formed on the nucleation layer 104, wherein the gallium nitride layer 106 may be non-doped, or may be doped with a deep-level energy gradient dopant source, such as iron or carbon. The gallium nitride layer 106 has a third thickness T3. In some embodiments, the third thickness T3 is a thickness within a range of T1*0.02% to T1*1%. In some preferred embodiments, the third thickness T3 is a thickness within the range of T1*0.04% to T1*0.5%. In some most preferred embodiments, the third thickness T3 is a thickness in the range of T1*0.1% to T1*0.3%. In one embodiment, when the first thickness T1 of the silicon carbide substrate 102 is 500 µm, the second thickness T2 of the nucleation layer 104 is, for example, 20 nm, and the third thickness T3 of the gallium nitride layer 106 is, for example, 1.5 µm. In other embodiments, the first thickness T1 of the silicon carbide substrate 102 may be 350 µm to 500 µm, and the third thickness T3 of the gallium nitride layer 106 is, for example, 0.3 µm to 2 µm.

Finally, referring to FIG. 3C, in some embodiments, a barrier layer 108 may be formed on the gallium nitride layer 106. In some embodiments, the barrier layer 108 may be made of materials including AlGaN, aluminum nitride (AlN) or indium aluminum nitride (InAlN), with a thickness of 1 to 30 nm, for example. After forming the barrier layer 108, the semiconductor structure in accordance with some embodiments of the present disclosure is accomplished.

In summary, in the semiconductor structure of the embodiment of the present disclosure, by controlling the thickness of the nucleation layer composed of AlGaN and controlling the aluminum content in AlGaN, the formed AlGaN layer can be continuously grown in 2D form, and can be used in subsequent steps to form an epitaxial layer of gallium nitride with lower stress. Accordingly, the formed semiconductor structure has good geometric quality, and the bow can be controlled within an appropriate range.

What is claimed is:

1. A semiconductor structure, comprising:
a silicon carbide substrate having a first thickness T1;
a nucleation layer located on the silicon carbide substrate and having a second thickness T2, wherein the nucleation layer is composed of aluminum gallium nitride (AlGaN), and the second thickness T2 is in a thickness range of T1*0.001% to T1*0.01%; and
a gallium nitride layer located on the nucleation layer and spaced apart from the silicon carbide substrate.

2. The semiconductor structure according to claim 1, wherein the second thickness T2 is in a thickness range of T1*0.002% to T1*0.007%.

3. The semiconductor structure according to claim 2, wherein the second thickness T2 is in a thickness range of T1*0.003% to T1*0.005%.

4. The semiconductor structure according to claim 1, wherein the AlGaN is represented by the following formula (1): 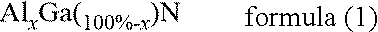
wherein in formula (1), an aluminum content X is in a range of 20% to 60%.

5. The semiconductor structure according to claim 4, wherein the silicon carbide substrate is a 4-inch silicon carbide wafer substrate.

6. The semiconductor structure according to claim 1, wherein the AlGaN is represented by the following formula (1): 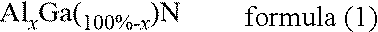
wherein in formula (1), an aluminum content X is in a range of 30% to 50%.

7. The semiconductor structure according to claim 6, wherein the silicon carbide substrate is a 6-inch silicon carbide wafer substrate.

8. The semiconductor structure according to claim 1, wherein the semiconductor structure has a bow in a range of -25 µm to +25 µm.

9. The semiconductor structure according to claim 1, wherein the semiconductor structure has a bow in a range of -5 µm to +5 µm.

10. The semiconductor structure according to claim 1, wherein the gallium nitride layer has a third thickness T3, and the third thickness T3 is in a thickness range of T1*0.02% to T1*1%.

11. The semiconductor structure according to claim 10, wherein the gallium nitride layer has the third thickness T3, and the third thickness T3 is in a thickness range of T1*0.04% to T1*0.5%.

12. The semiconductor structure according to claim 11, wherein the gallium nitride layer has the third thickness T3, and the third thickness T3 is in a thickness range of T1*0.1% to T1*0.3%.

13. The semiconductor structure according to claim 1, wherein the first thickness T1 is 500 µm.

14. The semiconductor structure according to claim 1, wherein the second thickness T2 is 20 nm.

15. The semiconductor structure according to claim 1, wherein the nucleation layer includes an AlGaN layer, the AlGaN layer includes a first side and a second side opposite to the first side, the first side is in contact with the silicon carbide substrate, and the second side is in contact with the gallium nitride layer, and an aluminum content in the AlGaN layer decreases from the first side to the second side.

16. The semiconductor structure according to claim 15, wherein the aluminum content in the AlGaN layer decreases in a linear manner.

17. The semiconductor structure according to claim 15, wherein the aluminum content in the AlGaN layer decreases in a non-linear manner.

18. A method of fabricating a semiconductor structure, comprising:
providing a regression plot diagram of a ratio of an aluminum content in aluminum gallium nitride (AlGaN) versus a bow of a semiconductor structure;
setting an ideal bow of the semiconductor structure to be formed, and calculating an ideal aluminum content according to the regression plot diagram;
providing a silicon carbide substrate;
forming a nucleation layer composed of AlGaN on the silicon carbide substrate according to the ideal aluminum content; and
forming a gallium nitride layer on the nucleation layer.

19. The method according to claim 18, wherein the ideal bow is set in a range of -25 µm to +25 µm.

20. The method according to claim 19, wherein when the semiconductor structure is a semiconductor structure used in high-power devices or radio frequency devices, the ideal aluminum content is in a range of 50% to 60%.
